(19) United States
(12) Patent Application Publication
(10) Pub. No.: US 2019/0348735 A1
(43) Pub. Date: Nov. 14, 2019

(54) LOW-LOSS MICROSTRIP PRINTED CIRCUIT BOARD FILTERING DEVICES

(71) Applicant: CommScope Italy S.r.l., Agrate Brianza (IT)

(72) Inventors: Huan WANG, Richardson, TX (US); Yuhua WANG, Shanghai (CN); Giuseppe RESNATI, Seregno (IT)

(21) Appl. No.: 16/337,604

(22) PCT Filed: Sep. 14, 2017
(86) PCT No.: PCT/CN2017/101668

§ 371 Date: Mar. 28, 2019

(30) Foreign Application Priority Data
Oct. 31, 2016 (CN) 201610930225.6

(51) Int. Cl. H01P 1/213; H05K 1/14; H01P 3/08

(52) U.S. Cl. CPC H01P 1/2135; H01P 3/087; H05K 1/145

(57) ABSTRACT

A suspended microstrip filtering device comprises a printed circuit board that includes a substrate having at least one resonator thereon, a ground plate, and an insulating separator interposed between the printed circuit board and the ground plate, the insulating separator having a plurality of air-filled openings.

### CROSS-REFERENCE TO RELATED APPLICATION

The present application claims priority under 35 U.S.C. § 119 from Chinese Patent Application Serial No. 201610930225.6, filed Oct. 31, 2016, the entire content of which is incorporated herein by reference.

### FIELD

The present invention relates generally to communications systems and, more particularly, to filtering devices that are suitable for use in cellular communications systems.

### BACKGROUND

Cellular base stations are well known in the art and typically include, among other things, baseband equipment, radios and antennas. FIG. 1 is a highly simplified, schematic diagram that illustrates a conventional cellular base station 10. As shown in FIG. 1, the cellular base station 10 includes an antenna tower 30 and an equipment enclosure 20 that is located at the base of the antenna tower 30. A plurality of baseband units 22 and radios 24 are located within the equipment enclosure 20. Each baseband unit 22 is connected to a respective one of the radios 24 and is also in communication with a backhaul communications system 26. Three antennas 32 (labelled antennas 32-1, 32-2, 32-3) are located at the top of the antenna tower 30. Each antenna 32 may provide coverage to a pre-defined sector of the “coverage area” served by the base station 10. Coaxial cables 34 (which are bundled together in FIG. 1 to appear as a single cable) connect the radios 24 to the respective antennas 32. It will be appreciated that modern base station antennas typically include multiple phased arrays per antenna, each of which may be used to transmit and receive radio frequency (“RF”) signals at two different orthogonal polarizations. As such, both the antennas 32 and the radios 24 typically have multiple input/output ports and the actual base station configuration may be far more complicated than the highly simplified example that is provided for illustrative purposes in FIG. 1, and that far more cables. It will also be appreciated that in many cases the radios 24 are located at the top of the tower 30 instead of in the equipment enclosure 20 in order to reduce transmission losses.

Cellular base stations often use phased array antennas to provide increased antenna gain and/or to allow frequency reuse within a cell. A typical phased array antenna 32 may be implemented as one or more columns of radiating elements mounted on a panel, with perhaps ten radiating elements per column. Typically, each radiating element in a column is used to (1) transmit radio frequency (“RF”) signals that are received from a transmit port of an associated radio 24 and (2) receive RF signals from mobile users and feed such received signals to the receive port of the associated radio 24. Duplexers are typically used to connect the radio 24 to each respective radiating element of the antenna 32. A “duplexer” refers to a three-port filtering device that is used to connect both the transmit and receive ports of a radio to an antenna (or to one or more radiating elements thereof). The duplexer isolates the RF transmission paths to the transmit and receive ports of the radio from each other while allowing both RF transmission paths access to the antenna. In other words, a duplexer separates RF signals flowing in one direction based on the frequency thereof while allowing signals in the full frequency range to flow in the opposite direction. Typically, the transmit and receive frequency ranges are very close to each other, and the combination of the transmit and receive frequencies are considered to be a single frequency “band.”

In some cases, the radiating elements on a phased array antenna may comprise “wideband” radiating elements. Such wideband radiating elements may be used to transmit and receive RF signals in two or more different frequency bands. When wideband radiating elements are used, two or more radios that operate in different frequency bands may be coupled to the same column of radiating elements of a phased array antenna. RF diplexers or multiplexers may be used to separate the RF signals received at the radiating elements from each other for delivery to the respective radios, and to combine signals transmitted from the different radios for delivery to the radiating elements. When such wideband radiating elements are used, the antenna will typically include both diplexers for separating/combining signals in the different frequency bands and duplexers for separating/combining the transmit and receive paths within each frequency band.

As base station antennas become more complex to support a greater number of cellular services, the number of diplexers, duplexers, multiplexers and other filtering devices integrated into the antenna or otherwise provided on the tower has proliferated. Consequently, the size, weight and cost of these filtering devices has become an increasing concern. The trend to an increasing number of filtering devices has been exacerbated by the widespread incorporation of remote electronic tilt (“RET”) capabilities into base station antennas. With RET antennas, the effective tilt or “elevation” angle of the antenna beam can be adjusted electronically by, for example, controlling phase shifters that adjust the phase of the signal fed to each radiating element (or to sub-arrays of radiating elements) of the antenna 32. The phase shifters and other related circuitry are typically built into the antenna 32 and can be controlled from a remote location. This capability greatly simplifies the process of changing the effective coverage area for a base station antenna, as is often done as new base stations are brought into service in adjacent regions.

A RET antenna typically has both transmit and receive path phase shifters so that the tilt on each sub-band may be independently controlled. The transmit path phase shifters perform power dividing so that a single signal from a radio may be provided to multiple radiating elements or sub-arrays of radiating elements (with a phase shifter dividing the RF signal into five to seven sub-components being typical). The receive path phase shifters perform power combining so that the signals received at the radiating elements may be combined and fed to the receive port of the radio. As separate transmit and receive phase shifters are used, the duplexers that are used to allow each radiating element to both transmit and receive signals must necessarily be located along the RF transmission path between the phase shifters and the radiating elements. Thus, if each phase shifter performs, for example 1:7 power division, then seven duplexers are required for each pair of transmit and receive phase shifters. This further expands the number of filtering devices that are included in the antenna.

Conventionally, resonant cavity filtering devices have been used to implement the above-described duplexers, diplexers, multiplexers and other filtering devices for base station antennas. Resonant cavity filtering devices may be highly reliable and may provide sharp frequency responses. However, they also tend to be relatively large and heavy, and may be expensive to manufacture. FIG. 2 is a perspective view of a conventional resonant cavity duplexer 50. FIG. 3 is a partially exploded perspective view of the conventional duplexer 50 of FIG. 2 with the cover plate removed therefrom.

Referring to FIGS. 2-3, the conventional duplexer 50 includes a housing 60 that has a floor 62 and a plurality of sidewalls 64. A plurality of internal walls 68 extend upwardly from the floor 62 to divide the interior of the housing 60 into a plurality of cavities 70. Coupling windows within the walls 68 and openings between the walls 68 allow communication between the cavities 70. A plurality of resonating elements 76, such as dielectric or coaxial metal resonators, are mounted within the cavities 70. A cover plate 78 acts as a top cover for the duplexer 50 and may be secured to the housing 60 via screws 80. A plurality of tuning screws 90 are also provided. The tuning screws 90 may be adjusted to tune aspects of the frequency response of the duplexer 50 such as, for example, the center frequency of the notch in the filter response. An input port 82 may be attached to a transmit port of a radio (not shown) via a first cabling connection 83. An output port 84 may be attached to a receive port of the radio via a second cabling connection 85. A common port may connect the duplexer 50 to a radiating element of the antenna (not shown) via a third cabling connection (not shown). It should be noted that the device of FIGS. 2-3 comprises two duplexers that share a common housing, which is why the device includes more than three ports (the device includes a total of six ports, although all of the ports are not visible in the views of FIGS. 2-3).

The conventional duplexer 50 of FIGS. 2-3 may be relatively large, and hence it may be difficult to make room to mount a large number (e.g., ten) of these duplexers 50 on a single phased array antenna. The duplexer 50 may also be relatively heavy, which increases the loading on the antenna. The duplexer 50 also has a large number of parts making fabrication and assembly more expensive.

### SUMMARY

Pursuant to embodiments of the present invention, suspended microstrip filtering devices are provided that include a printed circuit board having a substrate with at least one resonator thereon; a ground plate; and an insulating separator interposed between the printed circuit board and the ground plate, the insulating separator having a plurality of air-filled openings. In some embodiments, the at least one resonator is electrically floating.

In some embodiments, the printed circuit board is a first printed circuit board, the filtering device further includes a second printed circuit board that is spaced apart from and in a vertically stacked relationship with the first printed circuit board, and the second printed circuit board also includes at least one resonator thereon.

In some embodiments, the suspended microstrip filtering device further includes a third printed circuit board between the first printed circuit board and the second printed circuit board, where the ground plate comprises a conductive layer on a top surface of the third printed circuit board, and the third printed circuit board further includes a conductive layer on a bottom surface thereof that forms a second ground plate. In such embodiments, the insulating separator may be between the first printed circuit board and the third printed circuit board, and the suspended microstrip filtering device may further include a second insulating separator that has a plurality of air-filled openings between the second printed circuit board and the third printed circuit board.

In some embodiments, the insulating separator may be between the first printed circuit board and the third printed circuit board, and the suspended microstrip filtering device may further include a second insulating separator that has a plurality of air-filled openings between the second printed circuit board and the third printed circuit board. In some embodiments, the at least one resonator on the first printed circuit board may comprise a plurality of resonators that together form a first filter, and the at least one resonator on the second printed circuit board may comprise a plurality of resonators that together form a second filter, the first and second filters together forming the suspended microstrip filtering device.

In some embodiments, the first printed circuit board may have a first input/output port that is connected to a first microstrip transmission line on the third printed circuit board by a first jumper and a second input/output port that is connected to a second microstrip transmission line on the third printed circuit board by a second jumper.

In some embodiments, the suspended microstrip filtering device may further include a housing having a top cover, a bottom cover and at least one sidewall, the top cover, the bottom cover and the at least one sidewall defining an internal cavity. In some embodiments, the printed circuit board may extend outside the housing through an opening in the housing. In some embodiments, the housing may have an internal ledge, and at least one of the printed circuit board and the insulating separator may be mounted on the internal ledge.

In some embodiments, the insulating separator may have a fishnet pattern.

In some embodiments, the at least one resonator may comprise a plurality of resonators, and the suspended microstrip filtering device may further include a slidable tuning stub that is configured to capacitively couple with a first of the resonators. The slidable tuning stub may comprise, for example, a tuning element in the form of a conductive strip disposed on a tuning stub substrate, and the tuning stub substrate may be configured to slide on the first of the resonators and separate the conductive strip from the first of the resonators. In some embodiments, the slidable tuning stub may further include a tuning stub mounting structure that slidably mounts the tuning element above the first of the resonators.

In some embodiments, the slidable tuning stub may be configured to slide along a longitudinal axis of the first of the resonators. In other embodiments, the slidable tuning stub may be configured to slidably rotate above the first of the resonators.

In some embodiments, the suspended microstrip filtering device may be a multiplexer, a duplexer or a diplexer.

In some embodiments, the suspended microstrip filtering device may further include at least one metallic jumper that connects a conductive line input/output port of the device to a conductive line on a second printed circuit board. The metallic jumper may comprise, for example, a bent strip of metal.

Pursuant to further embodiments of the present invention, microstrip filtering devices are provided that include a substrate having a resonator thereon and a slidable tuning stub that is configured to capacitively couple with the resonator.

In some embodiments, the slidable tuning stub may comprise a tuning element in the form of a conductive strip disposed on a tuning stub substrate.

In some embodiments, the tuning stub substrate may be configured to slide on the resonator and to separate the conductive strip from the resonator.

In some embodiments, the slidable tuning stub may further include a tuning stub mounting structure that slidably mounts the tuning element above the first of the resonators. In some embodiments, the tuning stub mounting structure may comprise a clamp, a bolt and a nut.

In some embodiments, the slidable tuning stub may be configured to slide along a longitudinal axis of the resonator. In other embodiments, the slidable tuning stub may be configured to slidably rotate above the resonator.

In some embodiments, the substrate and the resonator may be part of a first printed circuit board, and the microstrip filtering device may further include a ground plate and an insulating separator interposed between the first printed circuit board and the ground plate, the insulating separator having a plurality of air-filled openings. In such embodiments, the microstrip filtering device may further include a second printed circuit board that is spaced apart from and in a vertically stacked relationship with the first printed circuit board, and the second printed circuit board may include at least one resonator thereon. In some embodiments, the device may further include a third printed circuit board between the first printed circuit board and the second printed circuit board, the ground plate may comprise a conductive layer on a top surface of the third printed circuit board, and the third printed circuit board may further include a conductive layer on a bottom surface thereof that forms a second ground plate.

### BRIEF DESCRIPTION OF THE DRAWINGS

FIG. 1 is a highly simplified, schematic diagram of a conventional cellular base station.

FIG. 2 is a perspective view of a conventional duplexer.

FIG. 3 is a partially exploded perspective view of the conventional duplexer of FIG. 2 with the cover plate removed therefrom.

FIG. 4 is a simplified block diagram of an example wireless communications system in which filtering devices according to embodiments of the present invention may be used.

FIG. 5 is a schematic perspective view of a conventional microstrip filtering device.

FIG. 6 is a graph illustrating the frequency response of the filtering device of FIG. 5.

FIG. 7 is a schematic top perspective view of a suspended microstrip filtering device according to embodiments of the present invention.

FIG. 8 is an exploded perspective view of the suspended microstrip filtering device of FIG. 7.

FIGS. 9A and 9B are schematic exploded perspective views of alternative implementations for the insulating separator that is included in the suspended microstrip filter of FIGS. 7-8.

FIG. 10 is a graph illustrating the frequency response of the suspended microstrip filtering device of FIGS. 7-8.

FIG. 11 is a schematic perspective view of a suspended microstrip filter that includes two resonator printed circuit boards according to embodiments of the present invention.

FIG. 12 is a cross-sectional view of the suspended microstrip filtering device of FIG. 11.

FIGS. 13 and 14 are exploded top and bottom perspective views, respectively, of the suspended microstrip filtering device of FIGS. 11-12.

FIG. 15 is a schematic perspective view of a resonator printed circuit board of a suspended microstrip filtering device that includes slidable tuning stubs according to embodiments of the present invention.

FIG. 16 is an enlarged side perspective view of a portion of the resonator printed circuit board of FIG. 15.

FIG. 17 is a schematic bottom perspective view of the resonator printed circuit board of FIGS. 15-16.

FIG. 18 is a schematic perspective view of a resonator printed circuit board of a microstrip filtering device that includes slidable tuning stubs according to further embodiments of the present invention.

FIG. 19 is a top perspective view of a suspended microstrip filtering device according to further embodiments of the present invention.

FIG. 20 is a top exploded perspective view of the suspended microstrip filtering device of FIG. 19.

FIG. 21 is a bottom perspective view of the suspended microstrip filtering device of FIG. 19.

FIG. 22 is a bottom exploded perspective view of the suspended microstrip filtering device of FIG. 19.

FIGS. 23 and 24 are an enlarged top view and an enlarged bottom view, respectively, of a portion of the suspended microstrip filtering device of FIG. 19 that illustrate how metal jumpers may be used to connect microstrip transmission lines on different printed circuit boards.

FIG. 25 is a graph illustrating the frequency response of the suspended microstrip filtering device of FIGS. 19-24.

FIG. 26 is a schematic block diagram that shows how suspended microstrip filtering devices according to embodiments of the present invention may be integrated into a larger microstrip system.

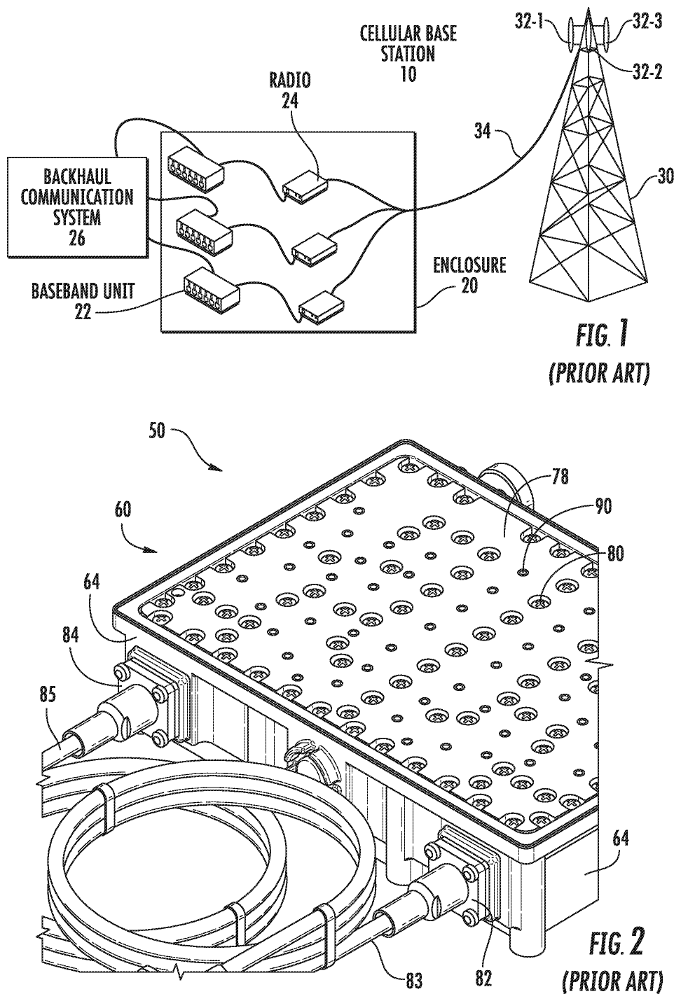

### DETAILED DESCRIPTION

As the number of cellular users and the amount of data transmitted and received by these users continues to rapidly increase, wireless operators are constantly looking for ways to increase throughput. Wireless operators have purchased additional wireless spectrum, but even the deployment of additional frequency bands and types of service has been insufficient to keep up with the growing demand. Accordingly, wireless operators are also aggressively taking steps to increase the throughput of existing wireless resources. One way to achieve this is to deploy a number of remote cellular sites that are smaller than traditional base stations that use frequency division multiplexers to divide the total available bandwidth into a series of non-overlapping frequency bands. This approach may significantly increase the available throughput, but it may be important that the remote sites be less expensive than a traditional base station while still providing high performance.

In the above-described cellular communications systems, the cellular sites may employ frequency division multiplexers to ensure that each remote site only transmits and receive signals on a subset of the total available bandwidth. Frequency division multiplexers are a known type of RF filtering device that allows input RF signals in selected frequency bands to pass to respective outputs. In its simplest form, a frequency division multiplexer may comprise a three port device that has a common input and first and second outputs. When RF signals are received at the common input, only signals in a first frequency range are passed to the first output while frequencies in a second frequency range are passed to the second output. Such three port filtering devices are referred to as diplexers if the first and second frequency ranges are part of different frequency bands, and as duplexers if the frequency ranges are the transmit and receive sub-bands of the same frequency band. Diplexers and duplexers also work as combiners in the opposite direction, combining the signals received at the first and second outputs and passing the combined signal to the common input.

Ideally, a frequency division multiplexer such as a diplexer will be relatively small, lightweight and low cost, and will also exhibit low losses. In practice however, in order to achieve small insertion losses and sharp frequency responses it has been necessary to implement frequency division multiplexers for cellular systems using metallic waveguide and/or resonant cavity filter technologies. These types of multiplexers tend to be larger, heavier and more expensive.

Embodiments of the present invention provide small, light, low cost and easily manufactured and assembled filtering devices that can be used as duplexers, diplexers, multiplexers and/or as other filtering devices for cellular communications systems and other applications. The filtering devices according to embodiments of the present invention may comprise microstrip filtering devices that are implemented using printed circuit board based resonators which may reduce the cost and weight of the device. Microstrip refers to a type of RF transmission line that may be implemented using printed circuit board technology. Microstrip consists of a conductive strip that is separated from a ground plane by a dielectric layer. Since microstrip may be formed simply by patterning printed circuit board metal layers it may be smaller, lighter and cheaper than conventional waveguide technology. The microstrip filtering devices according to embodiments of the present invention may exhibit low insertion loss values and may be readily tunable over a broad range of frequencies.

In some embodiments, the microstrip filtering devices may include a printed circuit board that comprises a dielectric substrate that has at least one conductive resonator thereon. Herein a printed circuit board that includes at least one resonator may be referred to as a “resonator printed circuit board.” A conductive ground plate may be disposed on a side of the dielectric substrate of the resonator printed circuit board that is opposite the resonator. An insulating separator is interposed between the dielectric substrate of the resonator printed circuit board and the ground plate. The insulating separator has a plurality of air-filled openings. By using an insulating separator that includes air-filled openings to separate the resonator printed circuit board and the ground plate, the filtering device has a “suspended microstrip” configuration. This suspended microstrip configuration may reduce the insertion loss of the filtering device, as the air space between the resonators and the ground plate may reduce the dissipation loss of the filtering device. In some embodiments, the insulating separator may comprise a dielectric material formed in a fishnet grid, but any suitable insulating separator that includes air filled openings may be used.

In some embodiments, an optional housing may be provided. The housing may comprise top and bottom cover plates and, in some embodiments, one or more sidewalls. When a housing is provided, the top and/or bottom cover plates may act as the ground plate of the filtering device.

In some embodiments, the suspended microstrip filtering devices may include a plurality of printed circuit boards that are arranged in a stacked relationship. For example, in some embodiments, the microstrip filtering device may comprise first and second printed circuit boards, each of which comprise a substrate having one or more resonators thereon. An insulating separator that has a plurality of air-filled openings is interposed between the first and second printed circuit boards. Top and bottom cover plates may be provided that act as the ground plates for the filtering device. In other embodiments, one or more ground plates may be inserted between the first and second printed circuit boards. In such embodiments, a first insulating separator that has a plurality of air filled openings is interposed between the first printed circuit board and the ground plate(s) and a second insulating separator that has a plurality of air filled openings is interposed between the second printed circuit board and the ground plate(s). The ground plate(s) may comprise, for example, a pair of printed circuit board ground plates that are formed on either side of a substrate of a third printed circuit board. A printed circuit board that includes a ground plate on at least one side thereof may be referred to herein as a “ground plate printed circuit board.” The ground plate printed circuit board may include other elements of the antenna such as phase shifters, feed lines or the like and may provide a convenient way to integrate the microstrip filtering devices according to embodiments of the present invention with other elements of a base station antenna in a low-loss, easy to manufacture assembly.

Pursuant to still further embodiments of the present invention, microstrip filtering devices are provided that include slidable tuning stubs. These slidable tuning stubs may comprise conductive strips formed on a dielectric substrate that are slidable relative to an underlying resonator. As the tuning stub moves relative to the underlying resonator, the amount of overlap between a conductive strip of the tuning stub and the resonator varies, which in turn varies the effective length of the resonator. By changing the effective length of the resonator, one or more resonant frequencies of the microstrip filtering device may be adjusted. In some embodiments, the slidable tuning stubs may slide longitudinally over top of respective resonators. In other embodiments, the slidable tuning stubs may slide rotationally over top of the respective resonators.

The shape and relative locations of the resonators, the distances between the resonator printed circuit boards and the ground plates and the distances between the resonator printed circuit boards can be designed to provide a microstrip filtering device having a desired filter (frequency) response. If a housing is provided, it can be implemented, for example, as a frame that forms the sidewalls of the housing and a pair of planar metal sheets that act as top and bottom covers that are soldered to the frame. The frame may be manufactured by, for example, die-casting or by using computer numerical control (“CNC”) machines or a cross section stretch process. One or more resonator printed circuit boards may be mounted within a cavity defined by the housing. In some embodiments, one or more ledges may extend around the interior of the frame, and the resonator printed circuit board(s) and/or insulating separator may be mounted on these ledges.

In some embodiments, the microstrip filtering devices may comprise three port devices such as RF duplexers or diplexers. In other embodiments, the microstrip filtering devices may include additional ports to implement multiplexers, triplexers or the like.

The microstrip filtering devices according to embodiments of the present invention may be readily integrated into other microstrip systems of a base station antenna or other RF device. For example, a resonator printed circuit board or a ground plate printed circuit board of the microstrip filtering devices according to embodiments of the present invention may be mounted on a printed circuit board that includes other printed circuit based elements of the antenna such as, for example, phase shifters or feed structures for sub-arrays or individual radiating elements, or even radio components such as mixers or amplifiers. By integrating multiple components on a monolithic printed circuit board it may be possible to further reduce insertion losses and/or to improve passive intermodulation (“PIM”) distortion performance, as will be explained in greater detail below.

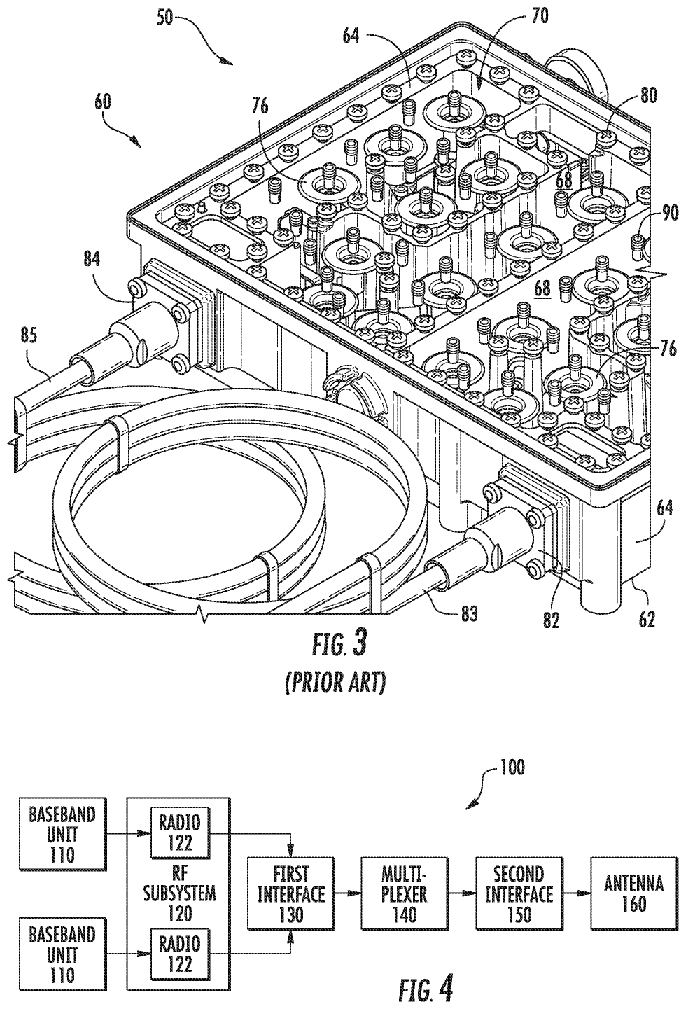

Embodiments of the present invention will now be described in greater detail with reference to FIGS. 4-26, in which example embodiments are depicted.

FIG. 4 is a simplified block diagram of an example wireless communications system 100 in which microstrip filtering devices according to embodiments of the present invention may be used. As shown in FIG. 4, the wireless communications system 100 includes one or more baseband units 110, an RF subsystem 120 that includes a plurality of radios 122, a multiplexer 140 and an antenna 160. The baseband units 110 are typically connected to the RF subsystem by cabling connections (e.g., coaxial cables and/or fiber optic cables along with optical-to-electrical and electrical-to-optical conversion). Digital-to-analog conversion (for signals to be transmitted by antenna 160) and analog-to-digital conversion (for signals received by antenna 160) may be performed between the baseband units 110 and the RF subsystem 120. The multiplexer 140 may comprise, for example, a duplexer or a diplexer. The example wireless communications system 100 further includes a first interface 130 between the RF subsystem 120 and the multiplexer 140 and a second interface 150 between the multiplexer 140 and the antenna 160. As will be explained below, in some embodiments of the present invention the first and second interfaces 130, 150 may each be implemented as microstrip interfaces.

One way to reduce the size, weight and cost of the wireless communications system 100 of FIG. 4 is to implement as much of the system as possible on a monolithic printed circuit board (“PCB”) structure. Such an implementation may reduce insertion loss and/or PIM distortion as connections between various components may be formed as microstrip connections, and may also provide for a more compact and/or lighter weight implementation. As noted above, conventionally metallic waveguide and resonant cavity filtering devices have been used to implement the multiplexer 140 in order to provide a sharp frequency response and low losses. Microstrip-based multiplexer filtering devices are also known in the art, but these filtering devices conventionally have exhibited relatively high insertion losses. As a 0.5 dB increase in insertion loss may decrease the power efficiency of a wireless communications system by 10%, the higher insertion losses associated with microstrip-based multiplexer filtering devices have precluded their use in many applications.

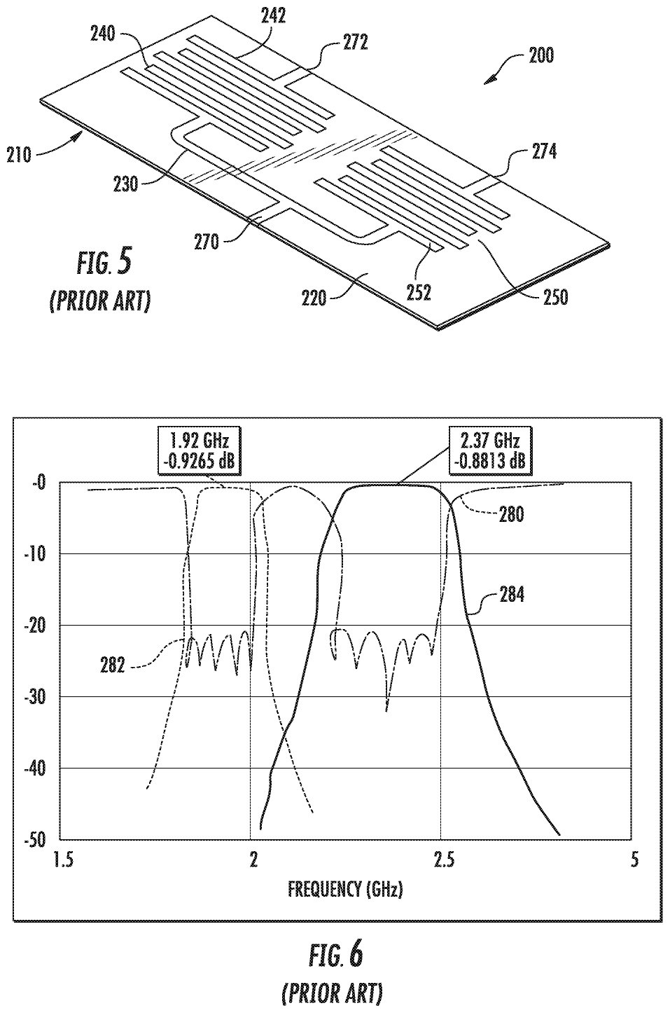

FIG. 5 is a schematic perspective view of a conventional microstrip diplexer filtering device 200. As shown in FIG. 5, the microstrip diplexer 200 comprises a microstrip printed circuit board 210 that includes a dielectric substrate 220 with conductive traces 230 thereon. The microstrip printed circuit board 210 may be formed by depositing a thin conductive layer (not shown) such as, for example, a copper layer on the dielectric substrate 220. The conductive layer may then be selectively etched to form the conductive traces 230. A conductive layer (not visible in FIG. 5) may also be formed on the back side of the dielectric substrate 220 that forms the ground plane for the microstrip. The conductive traces 230 may be disposed to form a low frequency filter 240 (i.e., a low-pass filter or a bandpass filter that passes a particular low frequency band) and a high frequency filter 250 (i.e., a high-pass filter or a bandpass filter that passes a particular high frequency band). Each filter 240, 250 may include a plurality of resonators 242, 252 in the form of, for example, strips of conductive material on the substrate 220. The microstrip diplexer 200 further includes a common microstrip port 270 that is coupled to both the low frequency filter 240 and the high frequency filter 250, a low frequency microstrip port 272 that is coupled to the low frequency filter 240 and a high frequency microstrip port 274 that is coupled to the high frequency filter 250. In cases where the diplexer 200 is used to implement the multiplexer 140 of FIG. 4, the common microstrip port 270 may comprise the second interface 150 of FIG. 4 that connects the multiplexer 140 to the antenna 160, and the low frequency microstrip port 272 and the high frequency microstrip port 274 may comprise the first interface 130 of FIG. 4 that connects the multiplexer 140 to the RF subsystem 120.

FIG. 6 is a graph illustrating the frequency response of the diplexer 200 of FIG. 5. In FIG. 6 curve 280 represents the return loss at the common microstrip port 270 while curves 282 and 284 represent the insertion loss on the low frequency and high frequency microstrip ports 272 and 274, respectively. As shown in FIG. 6, the insertion loss is nearly 1 dB (0.94 dB and 0.88 dB, respectively) at the center of the respective low-pass and high-pass frequency bands.

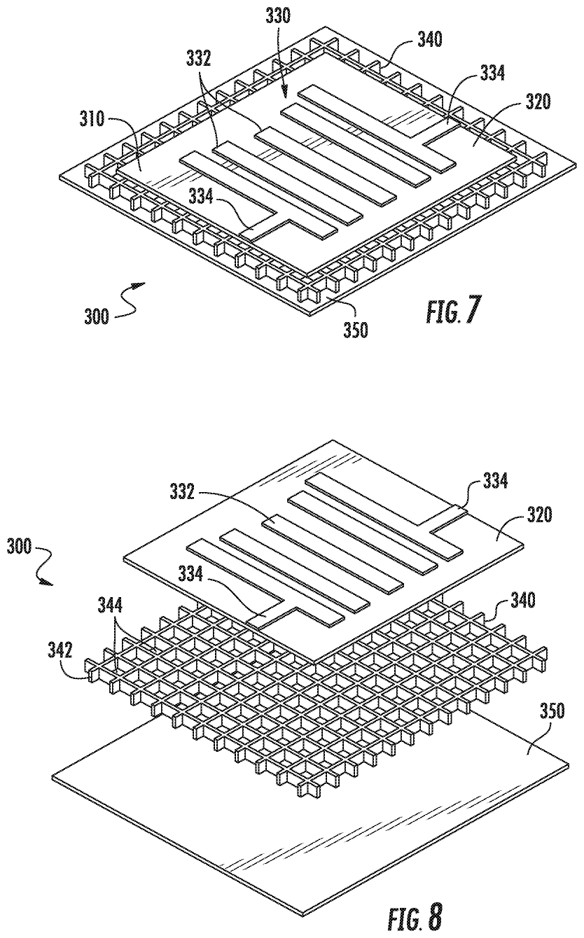

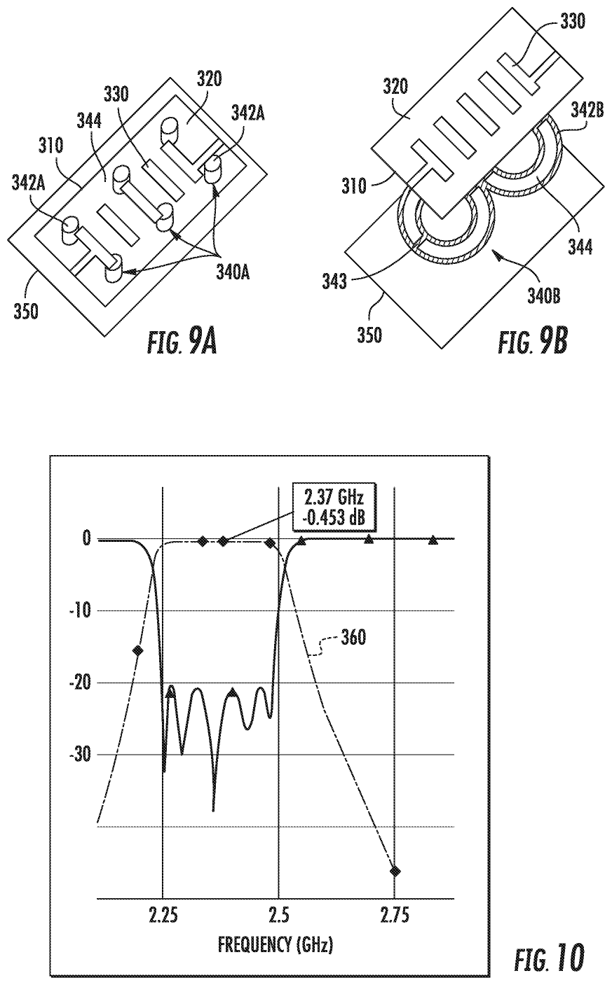

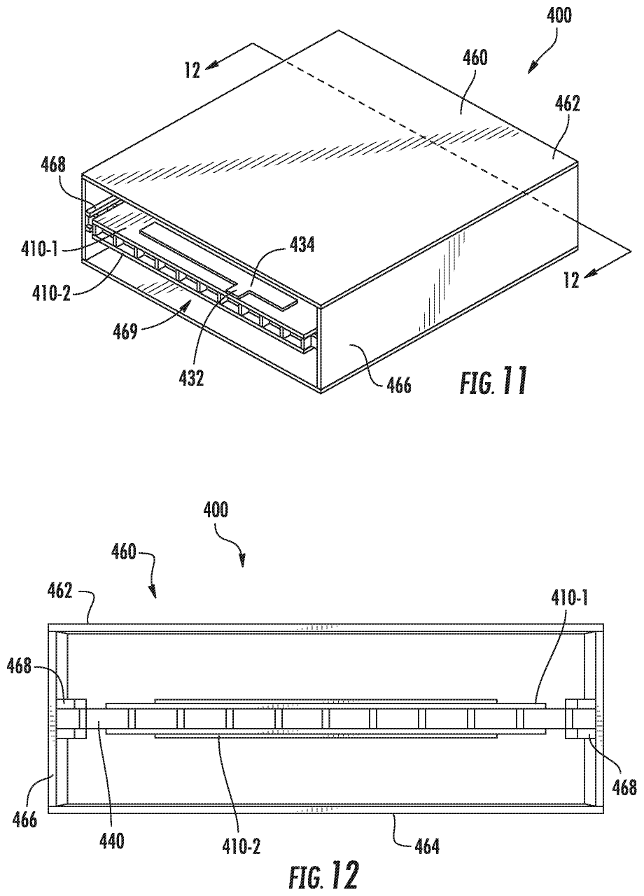

FIGS. 7 and 8 illustrate a suspended microstrip filtering device 300 according to embodiments of the present invention. In particular, FIG. 7 is a schematic top perspective view of the suspended microstrip filtering device 300, while FIG. 8 is an exploded perspective view of the suspended microstrip filtering device 300. FIGS. 9A and 9B illustrate alternative implementations for an insulating separator included in the suspended microstrip filtering device 300. FIG. 10 is a graph illustrating the frequency response of the suspended microstrip filtering device 300 of FIGS. 7-8.

As shown in FIGS. 7 and 8, the suspended microstrip filtering device 300 comprises a printed circuit board 310 that includes a dielectric substrate 320 that has conductive traces 330 formed thereon. The microstrip filtering device 300 further includes an insulating separator 340 and a ground plate 350. The microstrip printed circuit board 310 may be conventional in nature, except that the dielectric substrate 320 may be thinner than a conventional dielectric substrate for a microstrip printed circuit board, and the ground plane that is conventionally provided on the side of the dielectric substrate 320 that is opposite the conductive traces 330 is omitted. The dielectric substrate 320 may be formed of any suitable dielectric material. In some embodiments, the dielectric substrate 320 may comprise a standard FR-4 dielectric substrate. In other embodiments, the dielectric substrate 320 may comprise alumina. The conductive traces 330 may comprise, for example, copper or copper-alloy traces, and may be formed by patterning a copper layer that is initially provided on the dielectric substrate 320.

The insulating separator 340 may be any suitable structure that separates the microstrip printed circuit board 310 from the ground plate 350. In the depicted embodiment, the insulating separator 340 comprises a grid structure 342 that may be formed of a dielectric material. Openings 344 that are defined by the grid structure 342 may be air-filled openings. While the grid structure 342 comprises one example of an insulating separator, it will be appreciated that a wide variety of insulating separators 340 may be used. For example, as shown in FIG. 9A, in another embodiment, an insulating separator 340A may be used that comprises a plurality of discrete spacers 342A that are provided to space the printed circuit board 310 above the ground plate 350. In other embodiments, grid structures 342 that have different shaped or sized openings 344 may be used. For example, FIG. 9B illustrates an insulating separator 340B that includes a grid structure 342B that comprises dielectric material disposed in a plurality of concentric circles. As shown, in some embodiments, connecting bars 343 may be provided so that the grid structure 342B may comprise a unitary piece of material. The connecting bars 343 may be omitted in other embodiments. In each case, the grid structure 342A, 342B may include openings 344 that are filled with a gas such as, for example, air. As will be explained in greater detail below, the air-filled openings 344 may have a low loss constant which may decrease the insertion loss of the filtering device 300.

Referring again to FIGS. 7-8, the ground plate 350 may comprise a thin sheet of conductive material such as, for example, a thin copper sheet or a printed circuit board having a thin dielectric substrate with a sheet of conductive material on an upper surface thereof. As shown in FIGS. 7-8, the insulating separator 340 may be interposed between a top surface of the ground plate 350 and a bottom surface of the printed circuit board 310.

The conductive traces 330 may include a plurality of resonator traces 332 and input/output traces 334. The resonator traces 332 may be implemented, for example, as half-wavelength resonators or as quarter wavelength resonators. When quarter wavelength resonators are used, one end thereof may be electrically shorted to the ground plate 350 (e.g., for bandpass filters) or may be floating (e.g., for some band stop filters) In the depicted embodiment, half wavelength resonators 332 are provided. The input/output traces 334 may connect to other structures of, for example, an antenna in which the microstrip filtering device 300 is included. These connections may be direct connections or intervening structures may be interposed therebetween.

As is known to those of skill in the art, the insertion loss of an RF device refers to the amount of RF power that is lost as a result of interposing the RF device along an RF transmission line. RF power is lost when an RF signal traverses a microstrip printed circuit board due, for example, to coupling of the RF signal to the ground plane of the microstrip printed circuit board. Air has a very low loss constant, and hence by providing a primarily air dielectric between the conductive traces and the ground plane of the microstrip filtering device 300, the insertion loss of the filtering device 300 may be reduced as compared to conventional microstrip filtering devices.

FIG. 10 is a graph illustrating a portion of the frequency response of the suspended microstrip filtering device 300. As shown by curve 360 in FIG. 10, the insertion loss is less than 0.5 dB as compared to an insertion loss of about 0.9 dB with the conventional microstrip filtering device 300 discussed above. This reduction in insertion loss may increase the power efficiency of the filtering device by almost 10%.

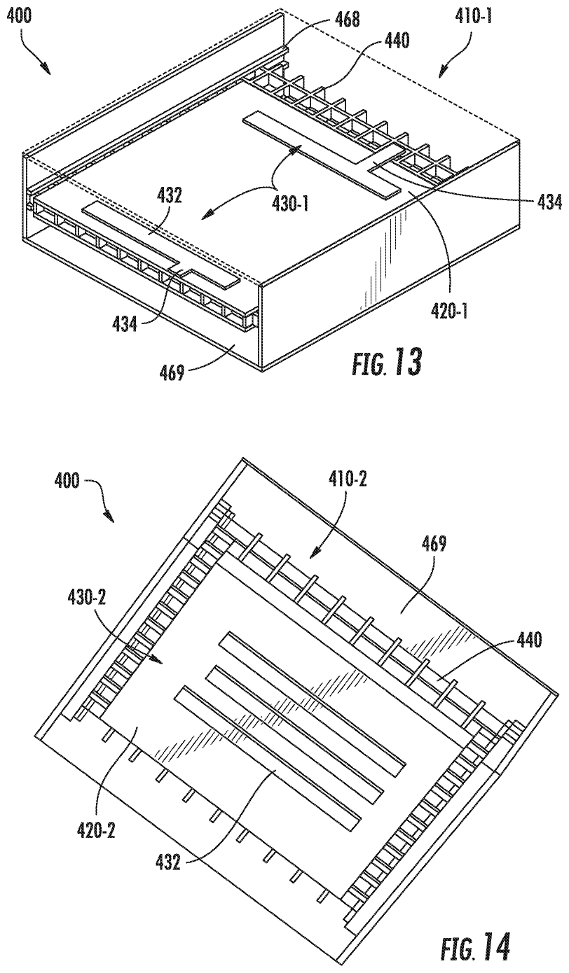

FIGS. 11-14 illustrate a suspended microstrip filtering device 400 according to further embodiments of the present invention. In particular, FIG. 11 is a schematic perspective view of the filtering device 400, FIG. 12 is a cross-sectional view of the filtering device 400 taken along line 12-12 of FIG. 11, and FIGS. 13 and 14 are exploded top and bottom perspective views, respectively, of the filtering device 400.

The filtering device 400 differs from the filtering device 300 in that it includes multiple printed circuit boards 410-1, 410-2 that are layered to form a multi-layer structure. As shown in FIG. 12, the multi-layer structure comprises a first microstrip printed circuit board layer 410-1, a second microstrip printed circuit board 410-2, and an insulating separator 440 disposed therebetween. The insulating separator 440 may, for example, be identical to the insulating separator 340 of filtering device 300 that is discussed above, although any suitable insulating separator may be used. In the depicted embodiment, the first printed circuit board 410-1 comprises a first dielectric substrate 420-1 that has conductive traces 430-1 thereon in the form of two resonators 432 (see FIG. 13) and the second printed circuit board layer 410-2 comprises a second dielectric substrate 420-2 that has conductive traces 430-2 thereon in the form of three resonators 432 (see FIG. 14). Printed circuit board 410-1 also includes input/output traces 434.

As is further shown in FIGS. 11-14, the suspended microstrip filtering device 400 also includes a conductive housing 460 that is used to support the printed circuit boards 410 and the insulating separator 440. The conductive housing 460 may also act to protect the printed circuit boards 410 and may serve as the ground plane of the microstrip elements. As shown in FIGS. 11 and 12, the conductive housing 460 may comprise a metal housing having a top cover 462, a bottom cover 464, and a plurality of sidewalls 466. The housing 460 may be formed, for example, of aluminium or an aluminium alloy that is plated with copper, although other metals may be used such as, for example, zinc, a zinc alloy, copper, a copper alloy, etc. While two sidewalls 466 are illustrated in FIGS. 11-14, it will be appreciated that additional sidewalls 466 may be added (e.g., front and back sidewalls so that the printed circuit boards 410 and insulating separator 440 are completely enclosed by the housing 460), or that the sidewalls 466 may be omitted altogether. In some embodiments, the sidewalls 466 may be implemented as a unitary die-cast frame. In the depicted embodiment, ledges 468 are provided on the interior surface of the sidewalls 466 that are used to mount the printed circuit boards 410 and insulating separator 440 in the middle of a cavity 469 defined by the housing 460. While the housing 460 is rectangular in the depicted embodiment, it will be appreciated that other shaped housings may be used (e.g., circular, pentagonal, etc.).

The resonators 432 on the first and second printed circuit boards 410-1, 410-2 form microstrip structures with the respective top cover 462 and bottom cover 464 act as the ground planes, with an air dielectric being interposed between the resonators 432 and their respective ground planes. The insulating separator 440 having the fishnet grid structure that is interposed between the printed circuit boards 410-1, 410-2 helps reduce the insertion loss for the filtering device 400. In some embodiments, the printed circuit boards 410-1, 410-2 may not be electrically connected to the housing 460.

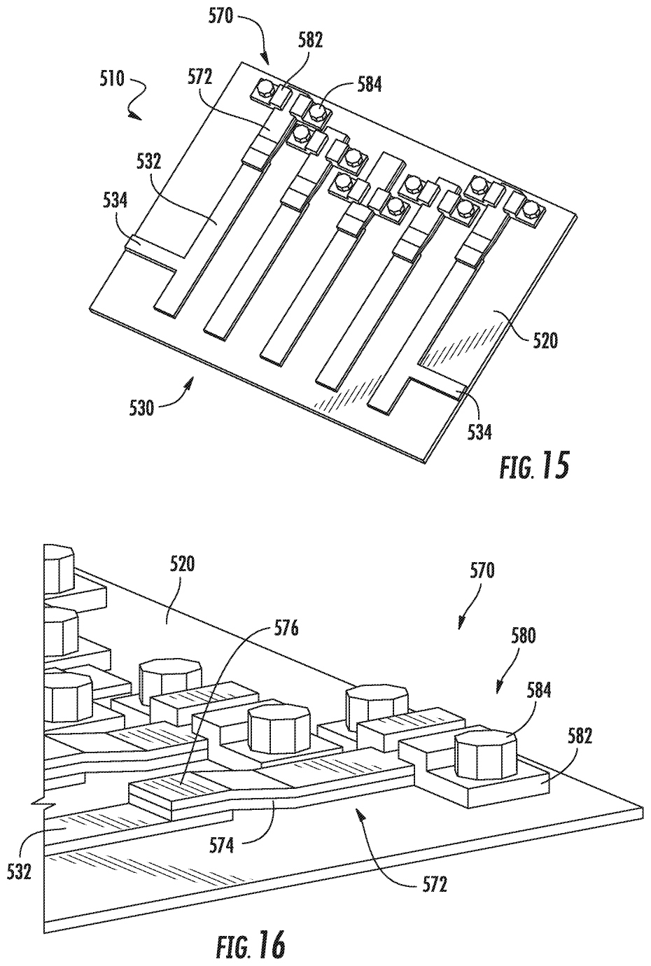

As noted above, conventional microstrip filtering devices may exhibit unacceptably high insertion losses. The suspended microstrip filtering device 400 may reduce these losses through the use of air dielectrics between the conductive traces 430 and the respective ground planes and through the use of the fishnet grid separator 440 that separates the printed circuit boards 410-1, 410-2 from each other. Another potential problem with conventional microstrip filtering devices is that they lacked tuning structures. Consequently, once a conventional microstrip filtering device was fabricated, it generally was not possible to tune characteristics of the device such as the location of pass bands and stop bands. Pursuant to embodiments of the present invention, tunable microstrip filtering devices are provided. FIGS. 15-18 illustrate two example implementations of slidable microstrip filtering device tuning structures according to embodiments of the present invention.

Referring first to FIGS. 15-17, a printed circuit board 510 of a microstrip filtering device is illustrated that includes slidable tuning stubs according to embodiments of the present invention. As shown in FIGS. 15-17, the printed circuit board 510 includes a dielectric substrate 520 that has a plurality of conductive traces 530 formed thereon. The conductive traces include resonators 532 such as, for example, half wavelength resonators and input/output traces 534. Each resonator 532 may include an associated slidable tuning stub 570.

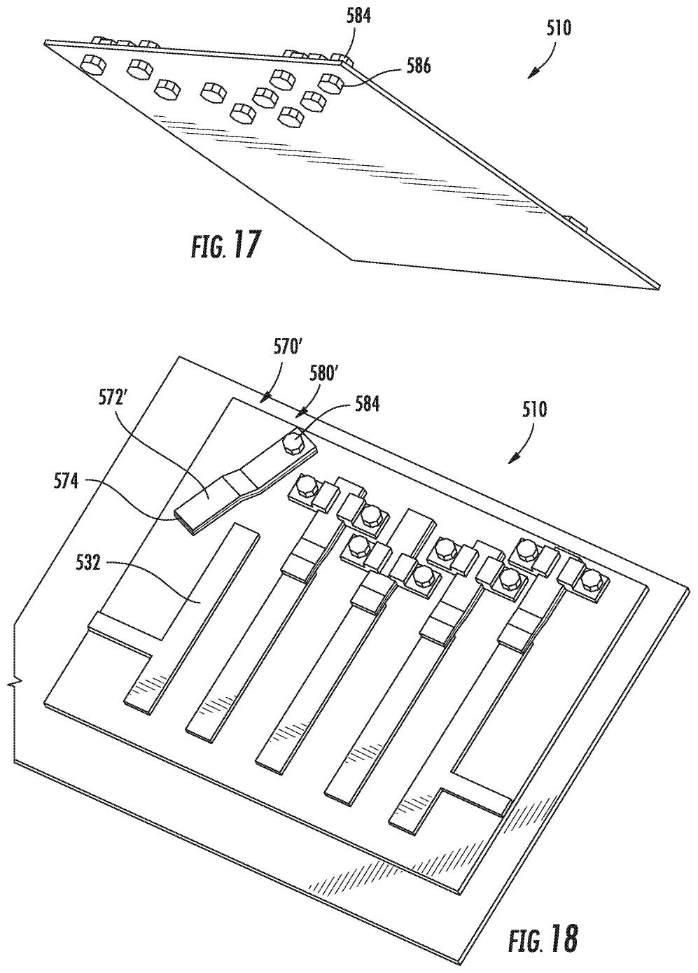

As can best be seen in FIG. 16, each slidable tuning stub 570 comprises a tuning element 572 and a tuning stub mounting structure 580. The tuning element 572 may comprise a finger of printed circuit board material that comprises a dielectric layer 574 with a conductive layer 576 on an upper surface thereof. The tuning element 572 in some embodiments may have a degree of flexibility. The dielectric layer 574 may insulate the conductive layer 576 from the underlying resonator 532. The tuning stub mounting structure 580 may comprise a pair of plastic clamps 582, a pair of plastic screws or bolts 584 and a pair of plastic nuts 586 (see FIG. 17). The bolts 584 are inserted through holes (not visible) in the respective plastic clamps 582 and through underlying openings in the dielectric substrate 520 of printed circuit board 510. The plastic nuts 586 (see FIG. 17) are positioned on the underside of the printed circuit board 510 and are threaded onto the respective bolts 584. When the nuts 586 are tightened onto the respective bolts 584, the plastic clamps 582 are firmly pushed down onto the respective tuning elements 572, thereby holding each tuning element 572 in a desired position. The nuts 586 may be loosened to adjust the respective positions of the tuning elements 572.

The dielectric layer 574 is thin so the conductive layer 576 couples strongly with its associated underlying resonator 532. Consequently, each tuning element 572 effectively extends the length of its associated resonator 532. The effective length of each resonator 532 is a function of the actual length of the resonator 532, the actual length of the portion of the tuning element 572 that does not overlap the resonator 532 and the amount of coupling between the resonator 532 and the tuning element 572. The amount of coupling between the resonator 532 and the tuning element 572 is a function of the distance between therebetween (which is the thickness of the dielectric layer 574), the amount of overlap between resonator 532 and the tuning element 572, and the dielectric constant of the dielectric layer 574. Accordingly, by sliding a tuning element 572 longitudinally along the resonator 532 the effective length of a resonator 532 may be changed.

In order to slide a tuning element 572, the nuts 586 of its tuning stub mounting structure 580 are loosened, thereby loosening the plastic clamps 582. The tuning element 572 may then slide longitudinally along its respective resonator 532. Thus, a technician can readily adjust the length of each resonator 532 in order to tune the filtering device. Once a tuning element 572 is at a desired level of overlap with its associated resonator 532, the nut 586 for that tuning element 572 may be tightened to hold the tuning element 572 in that location.

Referring to FIG. 18, in another embodiment, slidable tuning stubs 570′ are provided that may slidably rotate over top of a respective resonator 532. Since, as discussed above, the effective length of each resonator 532 is a function of, among other things, the amount of coupling between the resonator 532 and an associated tuning element, by rotating a tuning stub 570′ to partially overlap a resonator 532 the effective length of the resonator may be gradually changed (as increasing overlap results in increased coupling, and as the coupling increases the tuning stub 570′ results in increased effective length). The slidable tuning stubs 570′ include a slidable tuning element 572′ that may be identical to the slidable tuning elements 572 described above with reference to FIGS. 15-17, except that a hole is formed through the rear section of each slidable tuning element 572′. The slidable tuning stubs 570 further include a tuning stub mounting structure 580′ that comprises a plastic bolt 584 and a plastic nut 586. The bolt 584 is inserted through the above-referenced hole (not visible) in tuning element 572′ and through an underlying opening in the dielectric substrate 520 of printed circuit board 510. The plastic nut 586 (not visible in FIG. 18), which may be identical to the plastic nut 586 described above with reference to FIGS. 15-17, is positioned on the underside of the printed circuit board 510 and is threaded onto the plastic bolt 584. When the nut 586 is tightened onto the bolt 584, the slidable tuning element 572′ is firmly pressed against the printed circuit board 520 so that the slidable tuning element 572′ is locked into a desired position. When the nut 586 is loosened, the slidable tuning element 572′ may be rotated to either be over top of its associated resonator 532 or to be off to one side. When the slidable tuning element 572′ overlaps the resonator 532, the slidable tuning element 572′ capacitively couples with the resonator 532. As the amount of overlap increases, so does the amount of coupling between the slidable tuning element 572′ and the resonator 532, and as this coupling increases so does the effective length of the resonator 532. When the slidable tuning element 572′ does not overlap the resonator 532 the effective length of the resonator 532 is the actual length of the resonator 532. Thus, the slidably rotatable tuning elements 572′ can likewise be used to tune the filtering device.

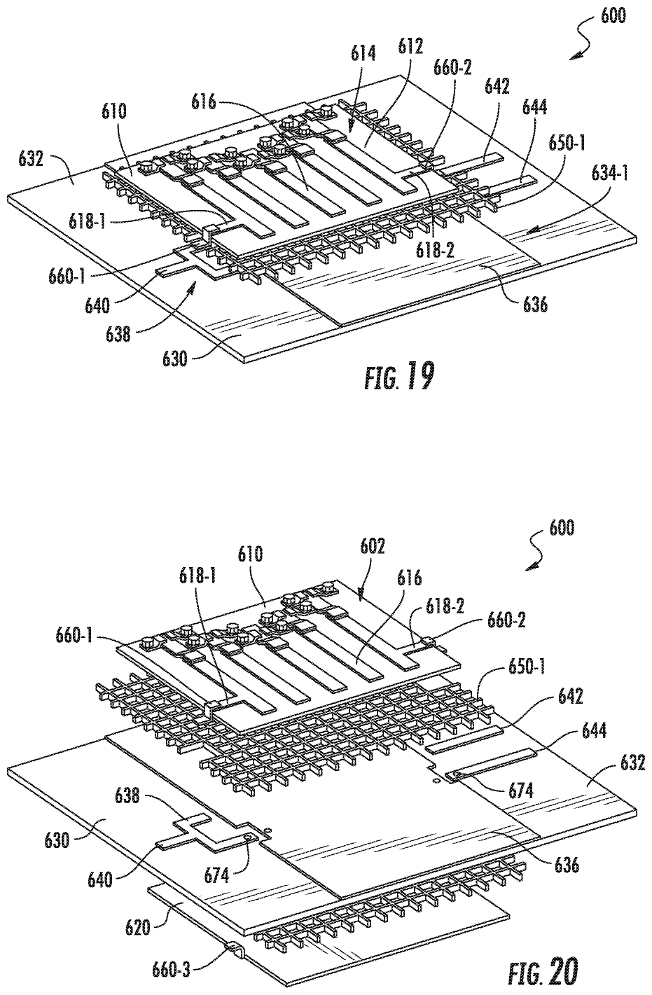

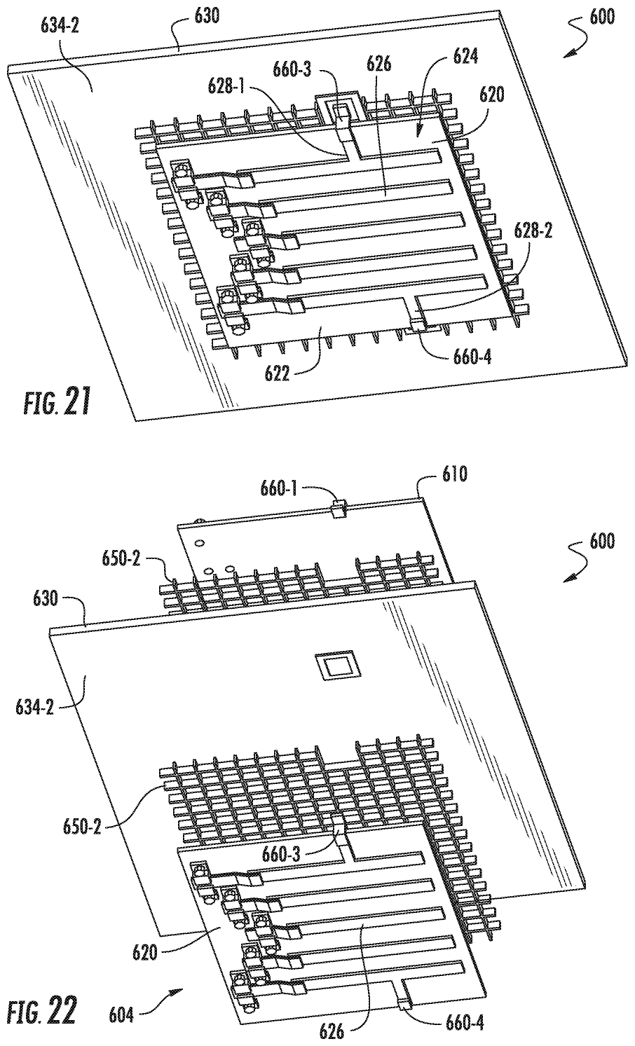

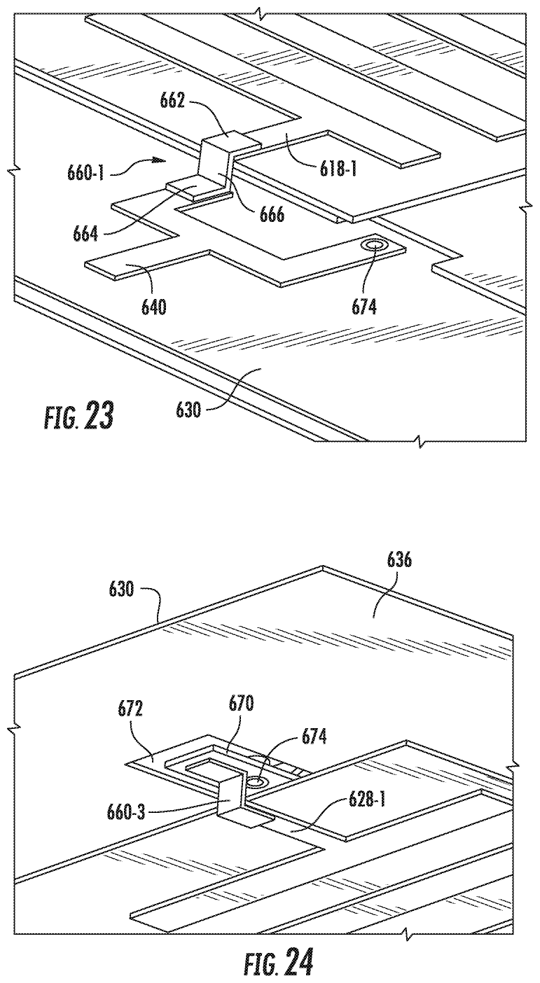

Pursuant to further embodiments of the present invention, suspended microstrip filtering devices are provided that may be integrated into other microstrip systems within a cellular base station. FIGS. 19-24 illustrate one such microstrip filtering device 600 according to embodiments of the present invention. In particular, FIGS. 19 and 21 are top and bottom perspective views, respectively, of the filtering device 600, and FIGS. 20 and 22 are respective top and bottom exploded perspective views of the filtering device 600. FIGS. 23 and 24 are enlarged top and bottom views, respectively, of a portion of the filtering device 600 that illustrate metal jumpers that are used to connect microstrip transmission lines on different printed circuit boards of the filtering device 600. While the example filtering device 600 shown in FIGS. 19-24 is a diplexer, it will be appreciated that any of the microstrip filtering devices according to embodiments of the present invention may be integrated in the same or similar manner into another microstrip system.

Referring to FIGS. 19-24, the microstrip filtering device 600 includes a first printed circuit board 610 and a second printed circuit board 620 that are arranged in a stacked vertical relationship. A third printed circuit board 630 is positioned between the first and second printed circuit boards 610, 620. The first printed circuit board 610 includes a dielectric substrate 612 having conductive traces 614 formed on a top surface thereof. The conductive traces 614 include resonators 616 and input/output ports 618. The resonators 616 may form a low frequency filter 602. The second printed circuit board 620 includes a dielectric substrate 622 having conductive traces 624 formed on a bottom surface thereof. The conductive traces 624 include resonators 626 and input/output ports 628. The resonators 626 may form a high frequency filter 604. The third printed circuit board 630 includes a dielectric substrate 632 having conductive layers 634-1, 634-2 formed on either side thereof. Each conductive layer 634 may include a conductive ground plane 636 and conductive traces 638. The conductive layer 634-1 serves as the ground plane for the low frequency filter 602, and the conductive layer 634-2 serves as the ground plane for the high frequency filter 604. A first insulating separator 650-1 is interposed between the first printed circuit board 610 and the third printed circuit board 630, and a second insulating separator 650-2 is interposed between the second printed circuit board 620 and the third printed circuit board 630. The insulating separators 650 are shown as fishnet grid separators, but any appropriate insulating separator may be used, including, for example, any of the insulating separators discussed herein.

The length of the resonators 616, 626, the distance between adjacent resonators 616, 626, the number of the location of the resonators 616, 626 may determine, at least in part, the frequency response of the filtering device 600.

The first printed circuit board 610 includes a first input/output port 618-1 and a second input/output port 618-2. The first input/output port 618-1 may be electrically connected to a common port for the filtering device 600, and the second input/output port 618-2 may be electrically connected to a low frequency port for the filtering device 600, as will be described below. The second printed circuit board 620 includes a first input/output port 628-1 and a second input/output port 628-2. The first input/output port 628-1 may be electrically connected to the common port for the filtering device 600 and the second input/output port 628-2 may be electrically connected to a high frequency port for the filtering device 600, as will also be described below. The third printed circuit board 630 includes three input/output ports 640, 642, 644. Port 640 may comprise the common port for filtering device 600, port 642 may be the low frequency port for filtering device 600, and port 644 may be the high frequency port for filtering device 600.

A first conductive jumper 660-1 connects port 618-1 to port 640. A second conductive jumper 660-2 connects port 618-2 to port 642. A third conductive jumper 660-3 connects port 628-1 to port 640. A fourth conductive jumper 660-4 connects port 628-2 to port 644. Port 642 may be connected (either directly or indirectly) to, for example, the receive port of a radio (not shown). Port 644 may be connected (either directly or indirectly) to, for example, the transmit port of the radio. Port 640, which is the common port of diplexer 600, may be connected to, for example, a radiating element of an antenna or a sub-array of radiating elements.

FIGS. 23 and 24 illustrate in greater detail how the conductive traces on the three printed circuit boards 610, 620, 630 are interconnected. As shown in FIG. 24, a small soldering pad 670 is formed on the bottom surface of printed circuit board 630. The solder pad 670, the ground plane 636 and the conductive traces 638 may be formed in a single processing step by selectively etching a conductive layer that is formed on the bottom surface of printed circuit board 630. The solder pad 670 is isolated from the ground plane 636 by an air gap 672. A metal filled hole 674 is formed in the substrate 632 of printed circuit board 630. The metal-filled hole 674 is formed through the solder pad 670. The metal-filled hole 674 extends all the way through the printed circuit board 630, and the metal that is deposited in the hole 674 electrically connects the solder pad 670 to the common port 640. While a metal-filled hole 674 is used to form the electrical connection in the embodiment of FIGS. 19-24, it will be appreciated that any suitable printed circuit board layer transfer technique may be used that electrically connects a conductive structure on a first layer of the printed circuit board to a conductive structure on a second, different layer of the printed circuit board 630. For example, a so-called plated through hole may be used in other embodiments which comprises a hole with sides that are plated with a conductive material, although the hole is not necessarily filled with the conductive material.

In the above-described manner, a first conductive path may be formed that extends from the common port 618-1 of the low frequency filter 602 to common port 640 on the printed circuit board 630 using conductive jumper 660-1. Likewise, a second conductive path may be formed that extends from the common port 628-1 of the high frequency filter 604 to solder pad 670 using conductive jumper 660-3. The solder pad 670 is connected to the common port 640 on the printed circuit board 630 though the metal-filled hole 674. In other words, the conductive jumpers 660-1, 660-3 may be used to connect the common ports 618-1, 628-1 of the respective low frequency and high frequency filters 602, 604 to the common port 640 on the printed circuit board 630. Conductive jumper 660-2 may similarly be used to connect the low frequency port 618-2 of the low frequency filter 602 to the low frequency port 642 on the third printed circuit board 630, and conductive jumper 660-4 may be used to connect the high frequency port 628-2 of the high frequency filter 604 to the high frequency port 644 on the third printed circuit board 630.

As shown best in FIGS. 23-24, the conductive jumpers 660 may be implemented as a small strip of metal that is bent to have a step structure that includes a first upper horizontal segment 662, a second horizontal segment 664 and a vertical segment 666 that connects the first horizontal segment 662 to the second horizontal segment 664. The first horizontal segment 662 may be soldered to a port of filter 602 or 604, and the second horizontal segment 664 may be soldered to a port on printed circuit board 630 or to a solder pad on printed circuit board 630 that is electrically connected to a port on printed circuit board 630.

FIG. 25 is a graph illustrating the frequency response of the diplexer 600. In FIG. 25 curve 690 represents the return loss at the common microstrip port 640 while curves 692 and 694 represent the insertion loss on the low frequency and high frequency microstrip ports 642 and 644, respectively. As shown in FIG. 25, the insertion loss is 0.5 dB or less (0.50 dB and 0.48 dB, respectively) at the center of the respective low and high frequency pass-bands.

While the diplexer 600 includes two printed circuit boards having filters formed thereon that are separated by a third “ground plane” printed circuit board, it will be appreciated that one or more additional printed circuit boards having resonators or ground planes formed thereon may be included in other embodiments.

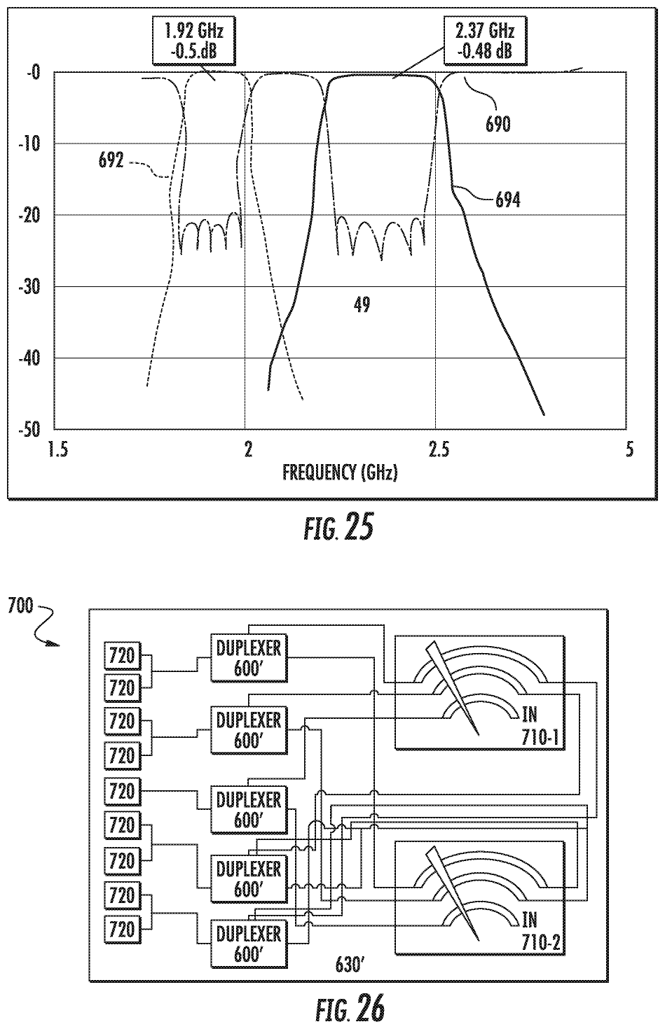

As discussed above, the suspended microstrip filtering devices according to embodiments of the present invention may readily be integrated into other microstrip systems. For example, a duplexer 600′ according to embodiments of the present invention may have the same general design as the suspended microstrip diplexer 600 discussed above with reference to FIGS. 19-24. The third printed circuit board of such a duplexer (i.e., a circuit board 630′ that corresponds to printed circuit board 630 of the suspended microstrip diplexer 600 may be a printed circuit board that is part of another microstrip system of, for example, a base station antenna. FIG. 26 is a schematic block diagram that shows how five suspended microstrip duplexers 600′ according to embodiments of the present invention may be integrated into a microstrip system 700 that includes two phase shifters and feed boards for nine radiating elements of a base station antenna.

As shown in FIG. 26, the microstrip system 700 is formed on a printed circuit board 630′ that may comprise a dielectric substrate having conductive traces thereon that serve as microstrip transmission lines. The conductive traces of the microstrip transmission lines may be formed on the top side of the dielectric substrate and a ground plane (not shown) may be provided underneath the conductive traces on the bottom side of the dielectric substrate. As is further shown in FIG. 26, first and second 1×5 phase shifters 710-1, 710-2 are formed on the printed circuit board 630′. The five outputs of phase shifter 710-1 are connected to the low frequency ports of the five duplexers 600′. The five outputs of phase shifter 710-2 are connected to the high frequency ports of the five duplexers 600′. The common ports of the five duplexers 600′ are connected to five sub-arrays of radiating elements. Four of the sub-arrays include two radiating elements 720 each while the fifth sub-array includes a single radiating element 720. The connections between the outputs of the phase shifters 710 and the duplexers 600′ may be microstrip transmission lines on the printed circuit board 630′. These may be low loss connections and may also avoid potential PIM problems that arise when coaxial cables or other connections are used that require connectors or soldered connections. Likewise, the connections between the common ports of the duplexers 600′ and the radiating elements 720 may be microstrip transmission lines on the printed circuit board 630′. The phase shifters 710 may be used to implement remote electronic tilt functionality for a base station antenna that includes the microstrip system 700.

The filtering devices according to embodiments of the present invention may provide a number of advantages over conventional filtering devices. As discussed above, microstrip filtering devices may be smaller, lighter and less costly to manufacture as compared to conventional resonant cavity filtering devices. Additionally, the filtering devices according to embodiments of the present invention may exhibit good PIM distortion performance. As is known in the art, PIM distortion may occur when two or more RF signals encounter non-linear electrical junctions or materials along an RF transmission path. Such non-linearities may act like a mixer causing new RF signals to be generated at mathematical combinations of the original RF signals. If the newly generated RF signals fall within the bandwidth of existing RF signals, the noise level experienced by those existing RF signals is effectively increased. When the noise level is increased, it may be necessary reduce the data rate and/or the quality of service. PIM distortion can be an important interconnection quality characteristic for an RF communications system, as PIM distortion generated by a single low quality interconnection may degrade the electrical performance of the entire RF communications system. Thus, ensuring that components used in RF communications systems will generate acceptably low levels of PIM distortion may be desirable.

One possible source of PIM distortion is an inconsistent metal-to-metal contact along an RF transmission path. Referring again to FIGS. 2-3, it can be seen that the conventional filtering device 50 includes a very large number of screws 80. Such a large number of screws 80 are used to ensure that relatively consistent metal-to-metal contacts are maintained to ensure acceptably low levels of PIM distortion. The filtering devices according to some embodiments of the present invention may eliminate the need for these screws, which may greatly simplify the device structure and reduce the time required to assemble the device.

Additionally, if screws are used to assemble a filtering device, when the screws are tightened, small metal shavings may be torn away from outer surfaces of the screws and/or from inner surfaces of the internally-threaded holes that receive the screws. Such metal shavings are another well-known source of PIM distortion in RF components, and may be particularly troubling as the metal shavings can move around inside the filtering device resulting not only in increased PIM distortion, but PIM distortion levels that can change over time in unpredictable ways. If increased PIM distortion levels are identified during a PIM distortion test during qualification of a particular unit, then the filtering device in question can be opened and cleaned to remove the metal particles. However, if the metal particles are not initially detected it can be a significant problem, as PIM distortion may arise later after the filtering device has been installed, for example, on an antenna that is mounted on a cell tower, requiring a very expensive replacement operation, downtime of the cellular base station, etc. It should be noted that the use of slidable tuning stubs in place of tuning screws may avoid generation of metal shavings within the device that could otherwise result from adjustment of tuning screws.

While in the above-described embodiments that include multiple printed circuit boards, the printed circuit boards are stacked vertically to have a top printed circuit board, a bottom printed circuit board and perhaps one or more intervening printed circuit boards, it will be appreciated that embodiments of the present invention are not limited to this arrangement. For example, in other embodiments, the printed circuit boards may be arranged in a housing in a side-by-side relationship.

The filtering devices described herein may be conventional from an equivalent circuit viewpoint in that they may have resonators and cross-couplings that are conventional in nature and which provide a conventional frequency response. However, the mechanical design of the filtering devices according to embodiments of the present invention may be much simpler than conventional filtering devices used in base station antennas and various other applications so that the filtering devices may have far fewer parts, a smaller physical footprint, are lighter weight than conventional filtering devices and far easier to manufacture and assemble.

It will be appreciated that a wide variety of filtering devices may be implemented using the above-described techniques. Thus, while the description above primarily focuses on three port filtering devices such as diplexers, it will be appreciated that more complex filtering devices such as triplexers, multiplexers and the like may be implemented using the techniques described herein.

While the description above focuses on microstrip filtering devices for base station antennas, it will be appreciated that embodiments of the present invention may be implemented into other RF systems without departing from the scope of the present invention. For example, the filtering devices described herein could be used in other types of antenna systems, in wired RF systems and various other applications.

The present invention has been described above with reference to the accompanying drawings, in which certain embodiments of the invention are shown. This invention may, however, be embodied in many different forms and should not be construed as limited to the embodiments set forth herein; rather, these embodiments are provided so that this disclosure will be thorough and complete, and will fully convey the scope of the invention to those skilled in the art.

In the above description, multiple instances of certain elements may be included in the embodiments shown in the figures. When this is the case, these elements may be referred to individually by a reference number that includes a dash (e.g., printed circuit boards 410-1 and 410-2), and may be referred to collectively by only the first portion of their reference number (e.g., the printed circuit boards 410).

Unless otherwise defined, all technical and scientific terms used herein have the same meaning as commonly understood by one of ordinary skill in the art to which this invention belongs. The terminology used in the description of the invention herein is for the purpose of describing particular embodiments only and is not intended to be limiting of the invention. As used in the description of the invention and the appended claims, the singular forms “a”, “an” and “the” are intended to include the plural forms as well, unless the context clearly indicates otherwise. It will also be understood that when an element (e.g., a device, circuit, etc.) is referred to as being “connected” or “coupled” to another element, it can be directly connected or coupled to the other element or intervening elements may be present. In contrast, when an element is referred to as being “directly connected” or “directly coupled” to another element, there are no intervening elements present.

In the drawings and specification, there have been disclosed typical embodiments of the invention and, although specific terms are employed, they are used in a generic and descriptive sense only and not for purposes of limitation, the scope of the invention being set forth in the following claims.

1. A suspended microstrip filtering device comprising:
a printed circuit board that includes a substrate having at least one resonator thereon;
a ground plate; and
an insulating separator interposed between the printed circuit board and the ground plate, the insulating separator having a plurality of air-filled openings.

2. The suspended microstrip filtering device of claim 1, wherein the printed circuit board is a first printed circuit board, the filtering device further comprising a second printed circuit board that is spaced apart from and in a vertically stacked relationship with the first printed circuit board, the second printed circuit board including at least one resonator thereon.

3. The suspended microstrip filtering device of claim 2, further comprising a third printed circuit board between the first printed circuit board and the second printed circuit board, wherein the ground plate comprises a conductive layer on a top surface of the third printed circuit board, the third printed circuit board further including a conductive layer on a bottom surface thereof that forms a second ground plate.

4. The suspended microstrip filtering device of claim 3, wherein the insulating separator is between the first printed circuit board and the third printed circuit board, the suspended microstrip filtering device further comprising a second insulating separator that has a plurality of air-filled openings between the second printed circuit board and the third printed circuit board.

5. The suspended microstrip filtering device of claim 2, wherein the at least one resonator on the first printed circuit board comprises a plurality of resonators that together form a first filter, and the at least one resonator on the second printed circuit board comprises a plurality of resonators that together form a second filter, the first and second filters together forming the suspended microstrip filtering device.

6. The suspended microstrip filtering device of claim 3, wherein the first printed circuit board has a first input/output port that is connected to a first microstrip transmission line on the third printed circuit board by a first jumper and a second input/output port that is connected to a second microstrip transmission line on the third printed circuit board by a second jumper.

7. (canceled)

8. The suspended microstrip filtering device of claim 1, further comprising a housing having a top cover, a bottom cover and at least one sidewall, the top cover, the bottom cover and the at least one sidewall defining an internal cavity, wherein the printed circuit board is at least partly within the internal cavity.

9. The suspended microstrip filtering device of claim 8, wherein the printed circuit board extends outside the housing through an opening in the housing.

10. The suspended microstrip filtering device of claim 8, wherein the housing has an internal ledge, and wherein at least one of the printed circuit board and the insulating separator is mounted on the internal ledge.

11. The suspended microstrip filtering device of claim 1, wherein the insulating separator has a fishnet pattern.

12. The suspended microstrip filtering device of claim 1, wherein the at least one resonator comprises a plurality of resonators, the suspended microstrip filtering device further comprising a slidable tuning stub that is configured to capacitively couple with a first of the resonators.

13. The suspended microstrip filtering device of claim 12, wherein the slidable tuning stub comprises a tuning element in the form of a conductive strip disposed on a tuning stub substrate, wherein the tuning stub substrate slides on the first of the resonators and separates the conductive strip from the first of the resonators.

14. The suspended microstrip filtering device of claim 13, the slidable tuning stub further comprising a tuning stub mounting structure that slidably mounts the tuning element above the first of the resonators.

15.-19. (canceled)

20. A microstrip filtering device comprising:
a substrate having a resonator thereon; and
a slidable tuning stub that is configured to capacitively couple with the resonator.

21. The microstrip filtering device of claim 20, wherein the slidable tuning stub comprises a tuning element in the form of a conductive strip disposed on a tuning stub substrate.

22. The microstrip filtering device of claim 21, wherein the tuning stub substrate slides on the resonator and separates the conductive strip from the resonator.

23. The microstrip filtering device of claim 20, the slidable tuning stub further comprising a tuning stub mounting structure that slidably mounts the tuning element above the first of the resonators.

24. (canceled)

25. The microstrip filtering device of claim 20, wherein the slidable tuning stub is configured to slide along a longitudinal axis of the resonator.

26. (canceled)

27. The microstrip filtering device of claim 20, wherein the substrate and the resonator are part of a first printed circuit board, the microstrip filtering device further comprising:
a ground plate; and
an insulating separator interposed between the first printed circuit board and the ground plate, the insulating separator having a plurality of air-filled openings.

28. The suspended microstrip filtering device of claim 27, the microstrip filtering device further comprising a second printed circuit board that is spaced apart from and in a vertically stacked relationship with the first printed circuit board, the second printed circuit board including at least one resonator thereon.

29.-30. (canceled)
